(19) United States
(12) Patent Application Publication
(10) Pub. No.: US 2010/0135061 A1
(43) Pub. Date: Jun. 3, 2010

(54) Non-Volatile Memory Cell with Ferroelectric Layer Configurations

(76) Inventors: Shaoping Li, Naperville, IL (US); Kaizhong Gao, Eden Prairie, MN (US); Insik Jin, Eagan, MN (US); Song Xue, Edina, MN (US); Haiwen Xi, Prior Lake, MN (US); Zheng Gao, Savage, MN (US); Eileen Yan, Edina, MN (US)

Correspondence Address: INTELLECTUAL PROPERTY GROUP;SEAGATE TECHNOLOGY FILES, FREDRIKSON & BYRON, PA, 200 SOUTH SIXTH ST, SUITE 4000, MINNEAPOLIS, MN, 55402-1425, US

(21) Appl. No.: 12/326,714

(22) Filed: Dec. 2, 2008

(51) Int. Cl. G11C 11/22; H01L 29/68

(52) U.S. Cl. 365/145; 257/295; 257/E29.17

(57) ABSTRACT

In some embodiments of the invention a non-volatile memory cell is provided with a first electrode, a second electrode, and one or more side layers of a ferroelectric metal oxide and a ferroelectric material layer between the first and second electrodes. The ferroelectric material layer may be provided between, e.g., adjacent, two side layers of a ferroelectric metal oxide or between a single layer of a ferroelectric metal oxide and an electrode. The ferroelectric metal oxide may in some cases include a uniform layered structure such as a bismuth layer-structured ferroelectric material like Bi₄Ti₃O₁₂. In some embodiments, the ferroelectric material layer is formed at least partially from PbZrₓTi₁₋ₓO₃. A non-volatile memory array including such memory cells is also provided.

### BACKGROUND

Memory with high density and speed, low power consumption, small form factor, and low cost continues to be in high demand.

Memory can either be classified as volatile or non-volatile. Volatile memory is memory that loses its contents when the power is turned off. In contrast, non-volatile memory does not require a continuous power supply to retain information. As such, non-volatile memory devices are widely employed in computers, mobile communications terminals, memory cards, and the like. Many non-volatile memories use solid-state memory devices as memory elements. In some cases, non-volatile memory devices have employed flash memory. In general, such a solid state memory device includes memory cells, each of which has a stacked gate structure. The stacked gate structure may include a tunnel oxide layer, a floating gate, an inter-gate dielectric layer, and a control gate electrode, which are sequentially stacked on a channel region.

Resistive random access memory (RRAM) is a potential replacement for flash memory because it promises high density, low cost and low power consumption. RRAM provides non-volatile memory storage through a reversible resistance change process in certain thin film media. A unit cell of the RRAM includes a data storage element which has two electrodes and a variable resistive material layer interposed between the two electrodes. The variable resistance layer, i.e., the data storage material layer, has a reversible variation in resistance according to the polarity and/or magnitude of an electric signal (voltage or current) applied between the electrodes.

RRAM employing ferroelectric thin film configurations promise to provide some of the highest areal densities because the memory effects are associated with interfacial effects such as the ferroelectric Schottky diode effect and the ferroelectric tunnel junction effect.

Unfortunately, limitations have been noted with respect to ferroelectric RRAM devices. For example, high leakage current density, retention failure, fatigue and imprint problems can lead to less than desirable performance. Embodiments of the present invention are focused on addressing these limitations of ferroelectric RRAM.

### SUMMARY

According to a first aspect of the invention, an exemplary non-volatile memory cell is provided including a first electrode, a first layer, formed from a ferroelectric metal oxide having at least two metals, adjacent the first electrode, a second electrode, and a second layer between the first layer and the second electrode. In some embodiments, the second layer is preferably formed from a ferroelectric material.

In some embodiments, the memory cell further includes a third layer, formed from a ferroelectric metal oxide having at least two metals, adjacent the second electrode. The second layer may be positioned between the first layer and the third layer, possibly adjacent one or more of the first and third layers.

In some embodiments, the ferroelectric metal oxides forming the first and third layers may be substantially the same material, although in some cases they may be different. For example, in some embodiments, the ferroelectric metal oxides have a uniform layered structure, which may in some cases include a bismuth layer-structured ferroelectric material such as Bi₄Ti₃O₁₂. In other cases, the ferroelectric metal oxides may include one or more of PbTiO₃, SrTiO₃, BaTiO₃, BaSrTiO₃, BaBiO₃, SrBi₄Ti₄O₁₅, SrBi₂Ta₂O₉, SrBi₂TaNaO₃, NaMgF₄, and KNO₃.

Similarly, in some embodiments, the ferroelectric material of the second layer is formed from a uniform layered material, such as a perovskite-structured material, for example, PbZrₓTi₁₋ₓO₃.

According to another aspect of the invention, a non-volatile memory cell is provided including a first electrode, a second electrode and a laminate between the first and second electrodes, wherein the laminate includes a first layer comprising a ferroelectric metal oxide, a second layer comprising the ferroelectric metal oxide, and a third layer between the first and second layers, the third layer comprising a ferroelectric material.

According to another aspect of the invention, some embodiments include a non-volatile memory array having multiple conductive array lines forming an upper layer and a lower layer, with the array lines of the upper layer crossing over the array lines of the lower layer to form multiple cross points between the array lines of the upper layer and the array lines of the lower layer. A layer of memory cells are also included, each memory cell including a ferroelectric stack electrically coupling one of the array lines of the upper layer with one of the array lines of the lower layer at one of the cross points. The ferroelectric stack of each memory cell may have a first layer comprising a ferroelectric complex metal oxide, a second layer comprising the ferroelectric complex metal oxide, and a third layer between the first and second layers, the third layer comprising a ferroelectric material. In some cases the ferroelectric complex metal oxide includes Bi₄Ti₃O₁₂ and the ferroelectric material includes PbZrₓTi₁₋ₓO₃.

### BRIEF DESCRIPTION OF THE DRAWINGS

FIG. 1 is a sectional view of a non-volatile memory cell in accordance with certain embodiments of the invention.

FIG. 2 is a section view of a non-volatile memory cell in accordance with certain embodiments of the invention.

FIG. 3A shows a current-voltage characteristic for a non-volatile memory cell having a Au/PZT/BIT/p-Si multilayer structure in accordance with certain embodiments of the invention.

FIG. 3B shows a current-voltage characteristic for a non-volatile memory cell having a Au/BIT/PZT/BIT/p-Si multilayer structure in accordance with certain embodiments of the invention.

FIG. 3C shows a current-voltage characteristic for a non-volatile memory cell having an electrode/ferroelectric/semiconductor multilayer structure.

FIG. 4A shows a capacitance-voltage characteristic for the non-volatile memory cell characterized in FIG. 3A.

FIG. 4B shows a capacitance-voltage characteristic for a non-volatile memory cell characterized in FIG. 3B.

FIG. 4C shows a capacitance-voltage characteristic for a non-volatile memory cell characterized in FIG. 3C.

FIG. 5 is a perspective view of a non-volatile memory cell array in accordance with certain embodiments of the invention.

### DETAILED DESCRIPTION OF THE PREFERRED EMBODIMENTS

The following detailed description should be read with reference to the drawings, in which like elements in different drawings are numbered identically. It will be understood that embodiments shown in the drawings and described herein are merely for illustrative purposes and are not intended to limit the invention to any embodiment. On the contrary, it is intended to cover alternatives, modifications, and equivalents as may be included within the scope of the invention as defined by the appended claims.

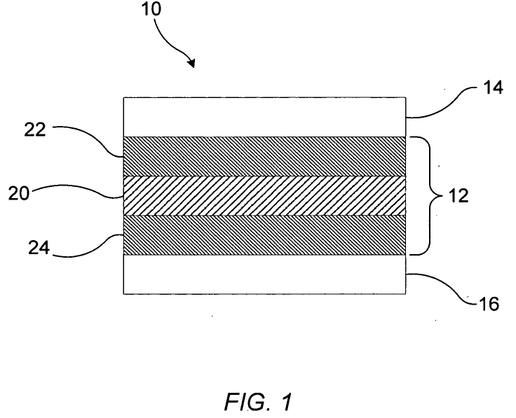

FIG. 1 is a sectional view of a non-volatile memory cell 10 incorporating multiple ferroelectric layers in accordance with some embodiments of the invention. The memory cell 10 generally includes a stack or laminate 12 having multiple ferroelectric material layers positioned between a first electrode 14 and a second electrode 16. As will be appreciated, the particular integration of the non-volatile memory cell 10 within a memory storage device (e.g., integrated circuit) will vary depending upon the specific design requirements for the particular embodiment. In many cases, the laminate 12 and first and second electrodes 14, 16 may further be formed adjacent a substrate (not shown). Further, additional layers (not shown) providing a number of features may also be included in certain embodiments depending upon the particular implementation.

In a preferred embodiment of the invention, the laminate 12 (or one or more layers within the laminate) exhibits a variable resistance under certain circumstances which allows it to store data in two or more states and makes the memory cell 10 useful for RRAM applications. One or more of the ferroelectric material layers within the stack include a variable resistance material that has a changes (e.g., reverses) resistance in response to certain polarities and/or magnitudes of an electrical signal (voltage or current) applied between the first and second electrodes 14, 16.

As previously mentioned, ferroelectric thin film configurations are especially useful for RRAM applications. In general, when an electrical signal energizes the laminate 12, one or more of the material layers within the laminate experience a remnant ferroelectric polarization that at least partially remains after the electrical signal is removed. The direction of the polarization depends upon the amplitude and polarity of the electrical. Data can be stored by assigning values to different polarizations. For example, one polarization direction may signify a set state, while the opposite polarization direction signifies a reset state. Each polarization state is associated with a unique resistance which affects current flow through the device. The polarization state, and thus the stored information, can be determined by sensing the conduction levels from the memory cell.

Ferroelectric materials have been used in past RRAM configurations, but with unfortunately less success than desired. For example, RRAM having a MIFS structure (metal/interface layer/ferroelectric p-type semiconductor/silicon) attempt to use ferroelectric thin films, but face a number of problems, including high leakage current density, retention failure, fatigue, and imprint limit their usefulness. Often times these types of problems stem from poor interface effects which can develop from serious interfacial reactions during the deposition of certain ferroelectric materials on a substrate, electrode, or other material. Embodiments of the invention address these and additional issues of concern.

In certain preferred embodiments, the memory cell 10 includes a ferroelectric material positioned adjacent one or more ferroelectric side layers between the first and second electrodes 14, 16.

For example, with reference to FIG. 1, a layer of ferroelectric material 20 is provided between a first ferroelectric side layer 22 and a second ferroelectric side layer 24. As used herein, “side layer” is used to differentiate the layers 22, 24 from the layer of ferroelectric material 20, and is not meant to limit the spatial arrangement and/or orientation of the layers. In some embodiments, the layer of ferroelectric material 20 may be formed adjacent the first and/or second side layers 22, 24 (e.g., without intervening layers), while the first side layer 22 may be provided adjacent the first electrode 14 and/or the second side layer 24 may be provided adjacent the second electrode 16.

In some embodiments, the layer of ferroelectric material 20 comprises a uniform layer-structured material having a strong polarization effect. For example, the ferroelectric material may comprise a perovskite-structured material such as one or more of PbTiO₃, SrTiO₃, BaTiO₃, BaSrTiO₃, and BaBiO₃. The ferroelectric material layer 20 may comprise a wide variety of other ferroelectric materials. For example, without meaning to limit the material composition, the layer 20 may comprise one or more of SrBi₄Ti₄O₁₅, SrBi₂Ta₂O₉, SrBi₂TaNaO₃, NaMgF₄, and KNO₃.

In one preferred embodiment, the ferroelectric material layer 20 comprises lead zirconium titanate (PbZrₓTi₁₋ₓO₃ or “PZT”). While PZT is a promising material for advanced ferroelectric memory configurations, it (and other ferroelectrics) can experience serious interfacial reactions during deposition onto other substrates and electrodes. In some embodiments, the first and/or second side layers 22, 24 function with the ferroelectric material layer 20 to limit these types of negative effects and enhance operation of the memory cell 10.

The first and second side layers 22, 24 comprise a complex ferroelectric metal oxide, e.g., a metal oxide having at least two metals in accordance with certain embodiments of the invention. In some cases the first and second side layers 22, 24 may comprise the same or substantially the same material, while in other embodiments the materials may include different complex ferroelectric metal oxides. In certain embodiments, one or both of the first and second side layers 22, 24 may have a uniform layered structure. For example, either or both of the side layers may comprise a bismuth layer-structured ferroelectric material such as c-axis Bi₄Ti₃O₁₂ (“BIT”). In some embodiments, the first and second side layers are formed from one or more complex metal oxides selected from the group consisting of PbTiO₃, SrTiO₃, BaTiO₃, BaSrTiO₃, BaBiO₃, SrBi₄Ti₄O₁₅, SrBi₂Ta₂O₉, SrBi₂TaNaO₃, NaMgF₄, and KNO₃.

Combinations of the first and/or second ferroelectric side layers 22, 24 advantageously cooperate with the layer of ferroelectric material 20 to reduce unwanted problems such as fatigue and imprint while enhancing the negative resistance effect, and thus the “readability” of the memory cell 10. For example, in some embodiments of the invention, the memory cell 10 (e.g., the laminate or stack 12) includes a combination of a PZT ferroelectric material layer and one or more side layers of BIT. The side layers and ferroelectric material layer may be configured in a variety of thicknesses depending upon the materials selected for a particular embodiment. In some embodiments, each layer is between about 1 nm to about 50 nm thick.

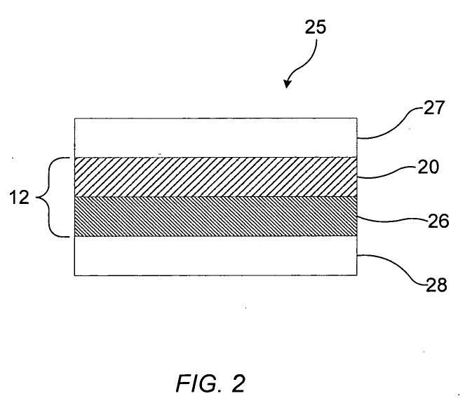

In some embodiments, enhanced performance may be obtained with only a single ferroelectric side layer. Referring to FIG. 2, in some embodiments, a memory cell 25 includes a layer of ferroelectric material 20 provided between a first ferroelectric side layer 26 and an electrode 27. In some embodiments, the layer of ferroelectric material 20 may be formed adjacent the first side layer 26 and/or the electrode 27 (e.g., without intervening layers), while the first side layer 26 may be provided adjacent another electrode 28. In some embodiments, the first side layer 26, the electrodes 27, 28, and the layer of ferroelectric material 20 comprise materials similar to those described above with respect to the embodiment of FIG. 1.

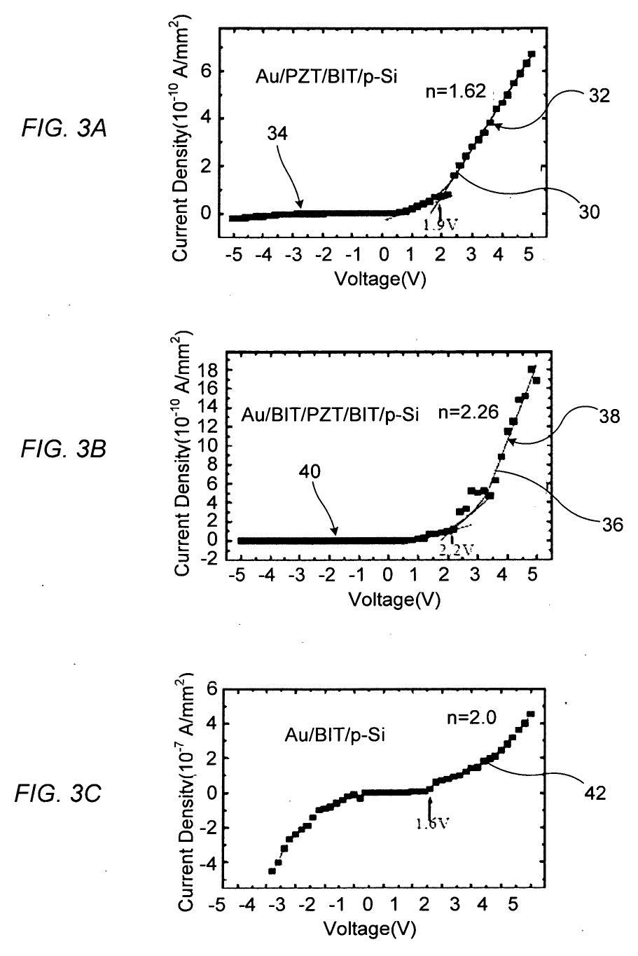

FIG. 3A is a current density-voltage (I-V) plot 30 showing a configuration with a single side layer of BIT positioned next to a ferroelectric layer of PZT between two electrodes. The plot 30 could, for example, correspond to the single-side layer embodiment shown in FIG. 2. As can be seen, the exemplary configuration provides a negative resistive effect, with a clearly identifiable conductive state 32 and insulating state 34. Turning to FIG. 3B, a current density-voltage distribution plot 36 resulting from a BIT-PZT-BIT configuration is shown according to another embodiment. For example, the plot 36 could correspond to embodiments similar to the embodiment depicted in FIG. 1. This combination of ferroelectric material layers produces an even stronger negative resistance effect (nearly 3× that of the single BIT side layer embodiment in FIG. 3A), providing a clear distinction between the conductive state 38 and the insulating state 40 of the memory cell. This greatly contrasts with the I-V plot 42 for a single BIT layer structure shown in FIG. 3C. As can be seen, the single layer structure does not produce a negative resistive effect as in the embodiments shown in FIGS. 3A and 3B.

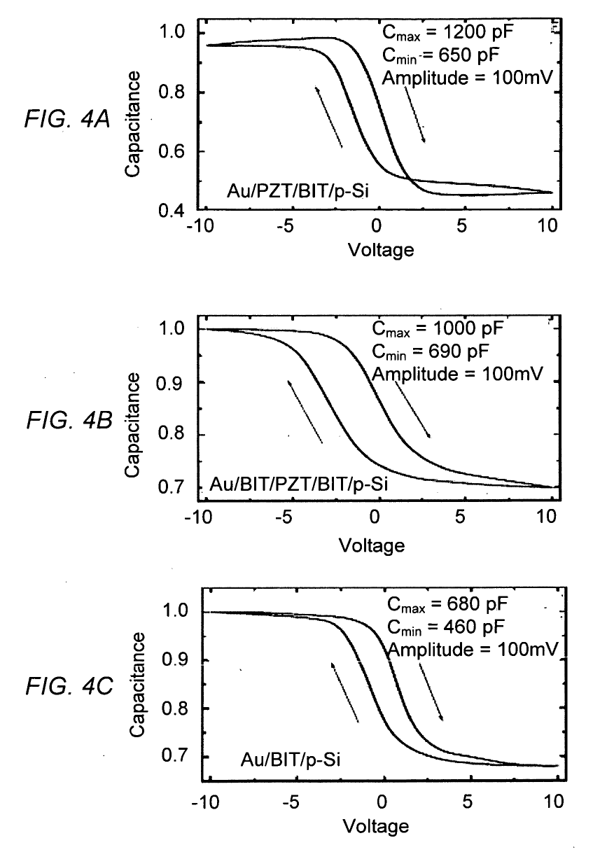

FIGS. 4A-4C show corresponding capacitance-voltage (C-V) characteristics for the structures of FIGS. 3A-3C. The curves show hysteresis loops typical for a MIFS structure with a ferroelectric p-type semiconductor having a gate negative to the p-type film. As can be seen, the BIT-PZT-BIT configuration of FIG. 4B provides a wide, open loop that implies increased data retention in the memory cell, while the other configurations provide this effect to a somewhat lesser degree.

The embodiments depicted in FIGS. 3 and 4 include one or more ferroelectric material layers positioned between electrodes of gold (Au) and p-doped polycrystalline silicon (p-Si or poly-Si). A wide variety of materials may be used for the first electrode and the second electrode, including, but not limited to one or more materials selected from the group consisting of Au, Cu. Ag, Al, Ta, Pt, SrRuO₃, RuO₂, poly-Si, YBa₂Cu₃Oₓ, IrO, La_{0.5}Sr_{0.5}CoO₃, and TiN. In some embodiments the first and second electrodes may be a similar or the same material, while in other embodiments, the material may be different for each electrode.

Various methods and processes may be used to make memory cells in accordance with the multiple embodiments of the invention. For example, the layer of ferroelectric material and the side ferroelectric layers can be made by various deposition techniques including rf-sputtering, DC reactive sputtering, e-beam evaporation, thermal evaporation, metal organic deposition, sol gel deposition, pulse laser deposition, and metal organic chemical vapor deposition. Of course, this list is not meant to be exhaustive, and the invention is not limited only to these techniques.

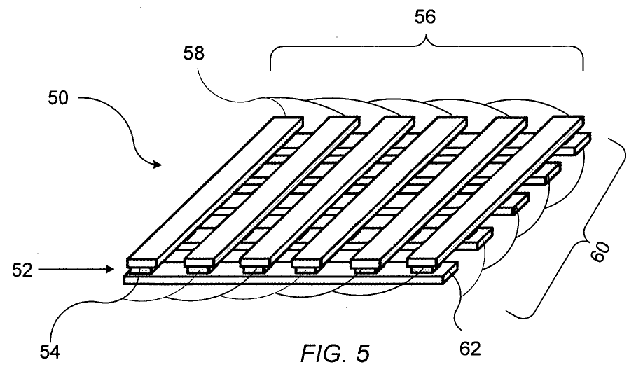

FIG. 5 depicts a perspective view of an exemplary non-volatile memory array 50 in accordance with certain embodiments of the invention. The non-volatile memory array 50 represents a memory structure, which can incorporate the memory cells embodied herein. In certain embodiments, the non-volatile memory array 50 form resistance random access memory (RRAM). In some embodiments, the invention may include multiple layers of memory, as in a stacked non-volatile memory array.

A structural benefit of using non-volatile memory array 50 is that the active circuitry (not shown) which drives the array 50 can be placed beneath the array, therefore reducing the footprint required on a semiconductor substrate. However, embodiments of the invention should not be limited to only cross-point arrays, as other types of memory arrays can be used with a two-terminal memory element. For example, a two-dimensional transistor memory array can incorporate a two-terminal memory cell. While the memory element in such an array would be a two-terminal device, the entire memory cell would be a three-terminal device.

As shown, the non-volatile memory array 50 of FIG. 5 employs a single layer 52 of memory cells 54. The single memory layer 52 is sandwiched between a top layer 56 of conductive array lines 58 and a bottom layer 60 of conductive array lines 62. In certain embodiments, as shown, the conductive array lines 58 of the top layer 56 and the conductive array lines 62 of the bottom layer 60 are positioned orthogonal to each other (e.g., the conductive array lines 58 oriented in the x-direction and the conductive array lines 62 oriented in the y-direction). At each of the cross points between the array lines 58 and 62, one of the memory cells 54 is provided. In certain embodiments, for each of the memory cells 54, one of the conductive array lines 58 of the top layer 56 acts as a first electrode, and one of the conductive array lines 62 acts as a second electrode. The conductive array lines 58 and 62 are used to both supply voltage to, and carry current through, the memory cells 54 in order to determine their corresponding resistive states. In certain embodiments, a select device such as a diode or transistor is included with the memory cells 54 at each of the cross points between the array lines 58 and 62 to control the current path throughout the non-volatile memory array 50. In certain embodiments, such select devices are connected in series with the memory cells 54 at the cross points.

The conductive array lines 58 and 62 of the top layer 56 and the bottom layer 60, respectively, can generally be constructed of any conductive material, such as Al, Cu, Pt, Ag, Au, Ru, W, Ti, TiN, other like materials, and certain conductive metal oxides such as SrRuO₃. Depending upon the material, a conductive array line would typically cross between 64 and 8192 perpendicular conductive array lines. Fabrication techniques, feature size and resistivity of material may allow for shorter or longer lines. Although the conductive array lines 58, 62 can be of equal lengths (forming a square cross point array), they can also be of unequal lengths (forming a rectangular cross point array), which may be useful if they are made from different materials with different resistivity.

With reference to FIG. 5, the point of intersection between any single conductive array line 58 and any single conductive array line 62 of the memory array 50 uniquely identifies one of the memory cells 54. As should be appreciated, the memory cells 54 are repeatable units that can be extended in one or two dimensions (e.g., with the memory array 50 of FIG. 4, in which the cells 54 are repeated in both x- and y-directions) or even three dimensions (e.g., a stacked memory in which the cells 54 are repeated in x-, y-, and z-directions). With continued reference to the array 50 of FIG. 5, one method of repeating the memory cells in the z-direction (orthogonal to the x-y-planes) is to use both the bottom and top surfaces of doubly-used conductive array lines (e.g., lines 62), thereby creating a stacked non-volatile array.

Thus, embodiments of the NON-VOLATILE MEMORY CELL WITH FERROELECTRIC LAYER CONFIGURATIONS are disclosed. Although the present invention has been described in considerable detail with reference to certain disclosed embodiments, the disclosed embodiments are presented for purposes of illustration and not limitation and other embodiments of the invention are possible. One skilled in the art will appreciate that various changes, adaptations, and modifications may be made without departing from the spirit of the invention and the scope of the appended claims.

What is claimed is:

1. A non-volatile memory cell, comprising:
a first electrode;
a first layer adjacent the first electrode, the first layer comprising a first ferroelectric metal oxide having at least two metals;
a second electrode; and
a second layer between the first layer and the second electrode, the second layer comprising a ferroelectric material.

2. The non-volatile memory cell of claim 1, further comprising a third layer adjacent the second electrode, the third layer comprising a second ferroelectric metal oxide having at least two metals, wherein the second layer is between the first layer and the third layer.

3. The non-volatile memory cell of claim 2, wherein the second layer is adjacent at least one of the first layer and the third layer.

4. The non-volatile memory cell of claim 3, wherein the second layer is adjacent the first layer and adjacent the third layer.

5. The non-volatile memory cell of claim 2, wherein the first and second ferroelectric metal oxides are substantially the same.

6. The non-volatile memory cell of claim 5, wherein the first and second ferroelectric metal oxides have a uniform layered structure.

7. The non-volatile memory cell of claim 2, wherein the first and second ferroelectric metal oxides each comprise a bismuth layer-structured ferroelectric material.

8. The non-volatile memory cell of claim 7, wherein at least one of the first and second ferroelectric metal oxides comprises Bi₄Ti₃O₁₂.

9. The non-volatile memory cell of claim 8, wherein each of the first and second ferroelectric metal oxides comprises Bi₄Ti₃O₁₂.

10. The non-volatile memory cell of claim 2, wherein the first and second ferroelectric metal oxides are selected from the group consisting of PbTiO₃, SrTiO₃, BaTiO₃, BaSrTiO₃, BaBiO₃, SrBi₄Ti₄O₁₅, SrBi₂Ta₂O₉, SrBi₂TaNaO₃, NaMgF₄, and KNO₃.

11. The non-volatile memory cell of claim 1, wherein the non-volatile memory cell comprises a resistive random access memory (RRAM) cell in at least a first resistive state or a second resistive state.

12. The non-volatile memory cell of claim 2, wherein the ferroelectric material of the second layer comprises a perovskite-structured material.

13. The non-volatile memory cell of claim 12, wherein the ferroelectric material comprises

14. The non-volatile memory cell of claim 2, wherein at least one of the first and second electrodes comprises a material selected from the group consisting of Au, Cu. Ag, Al, Ta, Pt, SrRuO₃, RuO₂, poly-Si, YBa₂Cu₃Oₓ, IrO, La_{0.5}Sr_{0.5}CoO₃, and TiN.

15. A non-volatile memory cell, comprising:
a first electrode;
a second electrode; and
a laminate between the first and second electrodes, the laminate comprising a first layer comprising a ferroelectric metal oxide, a second layer comprising the ferroelectric metal oxide, and a third layer between the first and second layers, the third layer comprising a ferroelectric material.

16. The non-volatile memory cell of claim 15, wherein the ferroelectric metal oxide comprises a uniform layer-structured material.

17. The non-volatile memory cell of claim 16, wherein the ferroelectric metal oxide comprises Bi₄Ti₃O₁₂.

18. The non-volatile memory cell of claim 17, wherein the ferroelectric material of the third layer comprises a perovskite-structured material.

19. The non-volatile memory cell of claim 18 wherein the ferroelectric material comprises

20. A non-volatile memory array, comprising:
a plurality of conductive array lines forming an upper layer and a lower layer, the array lines of the upper layer crossing over the array lines of the lower layer such that a plurality of cross points are formed between the array lines of the upper layer and the array lines of the lower layer; and
a layer of memory cells, each memory cell comprising a ferroelectric stack electrically coupling one of the array lines of the upper layer with one of the array lines of the lower layer at one of the cross points, the ferroelectric stack of each memory cell having a first layer comprising a ferroelectric complex metal oxide, a second layer comprising the ferroelectric complex metal oxide, and a third layer between the first and second layers, the third layer comprising a ferroelectric material.

21. The non-volatile memory array of claim 20, wherein the ferroelectric complex metal oxide comprises Bi₄Ti₃O₁₂ and the ferroelectric material comprises PbZrₓTi₁₋ₓO₃.
